(19) United States
(12) Patent Application Publication
(10) Pub. No.: US 2017/0261445 A1
(43) Pub. Date: Sep. 14, 2017

(54) Method for Monitoring a Process for Refining a Hydrocarbon Feedstock by NMR Measurement of Transverse Relaxation time T2

(71) Applicant: Total Raffinage Chimie, Courbevoie (FR)

(72) Inventors: Matthieu ADAM-BERRET, Thimeon (BE); Charles MARCHAL, Manage (BE); Maxime LACROIX, Uccle (BE); Gloria VENDRELL, Le Havre (FR)

(21) Appl. No.: 15/529,126

(22) PCT Filed: Nov. 24, 2015
(86) PCT No.: PCT/FR2015/053183

§ 371 Date: May 24, 2017

(30) Foreign Application Priority Data
Nov. 27, 2014 (FR) 1461593

(51) Int. Cl. G01N 24/08; C10G 45/00; G01R 33/421; C10G 45/16; G06F 17/15; G01R 33/28

(52) U.S. Cl. CPC G01N 24/082; G06F 17/156; G01R 33/285; G01R 33/421; C10G 45/16; C10G 45/00; C10G 2300/1096; C10G 2300/1059

(57) ABSTRACT

The invention relates to a method for monitoring a process for refining a feedstock of hydrocarbons, in which:
a) a signal representative of the transverse relaxation time of the different entities of an effluent resulting from said refining process, in particular an effluent comprising solid entities, is acquired by proton NMR,
b) the signal measured is modeled using a mathematical function comprising several components, each component corresponding to a dynamic range of the entities of said effluent,
c) the following are extracted from each of the components of the mathematical function:
   the transverse relaxation time of each of the components,
   the intensity of each of the components,
d) a value of parameter characteristic of said effluent is determined from at least one intensity determined in stage c),
e) a signal for controlling the refining process is generated as a function of said characteristic parameter.

### FIELD OF THE INVENTION

The present invention relates to a method for monitoring a process for refining hydrocarbon feedstock, the refining process making it possible to produce at least one petroleum product, in particular a heavy petroleum product.

Heavy petroleum products, in particular the residues from the distillation of oil and the effluents resulting from thermal conversion processes, catalytic cracking processes, hydrocracking processes, deep hydroconversion processes and processes for the hydrotreating of atmospheric or vacuum residues (ARDS or VRDS), are heavy hydrocarbon mixtures with a boiling point of greater than or equal to 350° C., denoted 350° C+. They are complex mixtures of hydrocarbons comprising colloidal systems consisting of asphaltenes.

Asphaltenes constitute the heaviest fractions of oil. They are glossy black solids, the molecular weight of which can vary from 1000 to 100 000 Da. Asphaltenes exhibit high contents of heteroelements and of metals: sulfur, nitrogen, nickel and vanadium. Asphaltenes can be defined as the family of molecules which are insoluble in n-pentane (Cₛ) or n-heptane (C₇).

### CONTEXT OF THE INVENTION

Asphaltenes are highly aromatic heavy molecules having paraffin side chains and heteroatoms, such as S and N, which are dispersed (or also known as “peptized”) in the form of micelles in a heavy oil or organic phase. Asphaltenes have a major influence on the physicochemical properties of the heavy products. This is because asphaltenes have an ability to flocculate and to be absorbed on surfaces and to form solid deposits. These colloidal systems can be destabilized more or less easily, for example by thermal cracking, by the severity of the processes or by dilution.

The flocculation and precipitation phenomena are the cause of many problems, both from the viewpoint of oilfield development and production and of refining, in particular in deep conversion processes, during the storage of the effluents or the mixing of said effluents. Asphaltenes are precursors of coke, deactivate the refining catalysts and detrimentally affect the operation of refining equipment.

The conversion and the severity of the refining processes can thus result in the formation of sediments, of coke and of a mesophase (phase preceding the formation of coke), which materials can accumulate inside the items of equipment of the refining unit. It may then be necessary to halt the plant and/or to provide maintenance at reduced time intervals. The monitoring of the content of sediments and of the appearance of coke may make it possible to limit the shutdowns, to reduce the maintenance operations and also to improve the quality of the products and to obtain more regular production.

The existing methods for monitoring the content of sediments and the appearance of coke require lengthy measurement times and the sometimes tedious preparation of the samples, so that they cannot be used for real-time control of a refining process.

The methods used are, for example, methods for the determination of the stability and of the content of solid, such as:
methods for the determination of the amounts of solid which are insoluble in toluene or xylene (by filtration), such as measurements of the content of sediment according to the standard ISO010307-2 or ISO 10307-1 or IP-375
methods for the determination of the S-value (for example according to ASTM D7157)
methods for the determination of the mesophase by XRD (X-Ray Diffraction) or polarized light,
TFT (Thermal Fouling Tester).

Other methods used are methods for the characterization of the asphaltenes in the colloidal state in underground formations.

There thus exists a need for a method for the simple and rapid monitoring of a process for the refining of a feedstock of hydrocarbons, in particular a refining process, one effluent of which is a petroleum product, in particular a heavy petroleum product comprising asphaltenes.

### DESCRIPTION OF THE INVENTION

There is thus provided a rapid and simple method for monitoring a process for the refining of a feedstock of hydrocarbons using proton NMR, in particular low field NMR or time-domain NMR.

To this end, a first subject matter of the invention is a method for monitoring a process for refining a feedstock of hydrocarbons, in which:
a) a signal representative of the transverse relaxation time of the different entities of an effluent resulting from said refining process, in particular an effluent comprising solid entities, is acquired by proton NMR,
b) the signal measured is modeled using a mathematical function comprising several components, each component corresponding to a dynamic range of the entities of said effluent, in particular each component corresponding to a transverse relaxation time T₂ and an intensity which is related to the amount of spins having this transverse relaxation time T₂,
c) the following are extracted from each of the components of the mathematical function:
   the transverse relaxation time of each of the components;
   the intensity of each of the components, this intensity being related in particular to the amount of spins having a similar dynamic;
d) a value of parameter characteristic of the solid entities of said effluent is determined from at least one intensity determined in stage c),
e) a signal for controlling the refining process is generated as a function of said value of said characteristic parameter of the solid entities.

The characteristic parameter thus makes it possible to characterize the solid entities exhibiting a more or less great stiffness, in other words to quantify the proportions of spins exhibiting different mobilities and in particular to quantify the most rigid protons. Entities having a transverse relaxation time T₂ of less than 0.2 ms can be regarded as solid entities.

The method according to the invention makes it possible in particular to monitor the quality of the mixtures, namely the mixtures of the different entities present in the effluent, and to identify, for example, the molecules which have not been converted by a conversion process.

Depending on the quality of the mixtures, it is possible to modify the operating parameters of the refining process, for example to reduce the severity, to increase or decrease the recycle ratio of the unit, to add more catalyst, to increase the degree of purging of the system, and the like.

Depending on the quality of the mixtures, it is also possible to direct the effluent, the NMR system of which is measured, in other words to decide on its future. The effluent can thus be recycled at the inlet of the refining process, be sent to another treatment or be isolated for the purpose of a specific use, for example as fuel, asphalt base or other.

It is thus understood that the monitoring method according to the invention can make it possible to monitor the quality of an effluent while generating a control signal which modifies the operating parameters of the refining process in order to maintain a predetermined quality of the effluent, or else which sends the effluent either as recycle in the refining process (as recycle or other) or to another treatment, or also which isolates it, depending on the quality of the effluent.

The monitoring method according to the invention exhibits the following advantages:
method not requiring sample preparation;
speed of the measurement;
carried out in a way predictive of a refining process;
choice of the future (recovery in value) of the effluent resulting from the refining process;
continuous monitoring of the refining process.

The NMR measurement is advantageously a low field NMR measurement.

Advantageously, the stage of generation of a control signal can comprise a stage of comparison of the value of the characteristic parameter of said effluent with at least one threshold value.

A threshold value can correspond to an optimum functioning of the refining process. This optimum functioning can be determined by operating the refining process at different levels of conversion or under different operating conditions for one and the same feedstock of hydrocarbons and by carrying out stages a to d) of the monitoring method according to the invention. The hydrocarbon feedstock used may be a feedstock identical to that which it is desired to monitor or a known feedstock chosen as reference. The value of the characteristic parameter determined in stage d) and corresponding to the point of optimum functioning of the process is then used as the threshold value. Additional analyses may optionally be carried out on the effluents in order to determine the point of optimum functioning of the process. These analyses can be the analyses normally used by a person skilled in the art to confirm or characterize the quality of an effluent. For example, determination of the softening point, of the viscosity, and the like, may be concerned.

Another threshold value may correspond to a predetermined quality of the effluent, the signal of which is measured. This threshold value may then be determined by carrying out stages a) to d) of the monitoring method according to the invention on an effluent obtained during the operation of the refining process under known predetermined conditions (for example known level of conversion, known operating conditions, and the like). Additional analyses may optionally be carried out on the effluent in order to characterize physical and/or chemical properties of use in determining its quality. Determination of the softening point, of the viscosity, and the like, may be concerned.

Advantageously, the control signal generated can be a signal for directing the operating conditions of the refining process and/or a signal for destination of the effluent. This signal can be an electrical signal, such as a voltage signal, an intensity signal or other. This control signal can be composed of a plurality of individual control signals, each individual signal controlling an operating condition of the process, for example, and/or controlling a destination of the effluent.

It is thus possible to control both the operating conditions of the refining process and the destination of the effluent, in particular in order to increase the amount of effluent used for a particular destination.

For example, in the case of the use of the method according to the invention to monitor a conversion, cracking, hydroconversion or desulfurization process, it is possible to monitor the process in order to obtain an effluent which can be recycled as feedstock of the refining process. In other words, it is possible to optimize the recycle ratio of the effluent by adjusting the operating conditions of the refining process and, when this recycle is not possible, to determine the destination of the effluent, which can then be sent to another treatment, used as asphalt base, as fuel, or other.

The operating conditions can include one or more of the following parameters: temperature, pressure, amount of catalysts, amount of feedstock, residence time or any other operating parameter of the refining process. The destination signal can be a signal indicating if the effluent has to be recycled as feedstock of the refining process or directed to a specific treatment or also stored for the purpose of a specific use.

### DETAILED DESCRIPTION OF THE INVENTION

Other advantages and characteristics will more clearly emerge from the description which will follow and the specific embodiments of the invention of which are given as nonlimiting examples.

The present invention consists in providing a method for monitoring a process for the refining of a feedstock of hydrocarbons by means of a parameter determined by proton NMR, this parameter being characteristic of an effluent petroleum product from the refining process.

The refining processes concerned can be chosen from:
atmospheric or vacuum distillation of crude oil,
thermal conversion processes, such as the visbreaking process,
catalytic cracking processes, such as the FCC (Fluid Catalytic Cracking) process,
hydrotreating, hydrocracking or deep hydroconversion processes (comprising a fixed bed, comprising a moving bed, ebullating bed, entrained bed, or in a slurry-phase reactor (the catalyst of which is in suspension)), or ARDS (Atmospheric Residue DeSulfurization) or VRDS (Vacuum Residue DeSulfurization) process,
physical separation processes, such as the deasphalting process.

The monitoring method according to the invention is particularly advantageous for the monitoring of visbreaking processes and slurry-phase processes (in which the catalyst is in the form of solid particles in suspension in the feedstock to be converted).

The effluent resulting from the refining process, the NMR signal of which is measured, can be an effluent from said process or can be a cut of the effluent from said process. It is generally a petroleum product comprising solid entities, for example asphaltenes, the content of which is variable according to the process, or comprising sediments. The effluents comprising asphaltenes and possibly sediments are, for example:
the atmospheric or vacuum residues resulting from the distillation of crude oil, which can comprise from 2 to 25% by weight of asphaltenes,
the effluents resulting from thermal conversion processes, such as the visbreaking process, which can comprise from 10 to 30% by weight of asphaltenes,
the slurry cut (350° C.+ cut) of the effluents resulting from catalytic cracking processes, such as the FCC process, which can comprise from 0.1 to 8% by weight of asphaltenes,
the 350° C.+ or 525° C.+ cuts of the effluent resulting from a slurry-phase hydroconversion process, also known respectively as atmospheric residue and final slurry vacuum residue (or slurry VR), which can comprise from 2 to 50% by weight of asphaltenes,
the effluents resulting from hydrotreating, hydrocracking or deep hydroconversion processes or from the ARDS or VRDS process, which can comprise up to 50% by weight of asphaltenes,
the pitches resulting from a physical separation process, for example deasphalting, which consists of a physical contact between a vacuum residue VR feedstock and C3 and C4 alkanes. These pitches can comprise from 4 to 50% by weight of asphaltenes.

The effluent, the NMR signal of which is acquired, can thus exhibit a content of asphaltenes of 0.1 to 8% by weight, of 1 to 5% by weight, of 2 to 25% by weight, of 5 to 20% by weight, of 7 to 20% by weight, of 10 to 20% by weight, of 10 to 30% by weight, of 15 to 30% by weight, of 4 to 50% by weight or of 15 to 50% by weight.

The process according to the invention is particularly suitable for the monitoring of slurry-phase hydroconversion processes; stage a) of acquisition of the NMR signal can then be carried out on the 350° C.+ or 525° C.+ cut of the effluent resulting from the slurry-phase hydroconversion process. In particular, the monitoring process according to the invention makes it possible to determine the most suitable recovery in value for the 350° C.+ or 525° C.+ cut. The control signal generated in stage e) can then comprise a signal for destination of the 350° C.+ or 525° C.+ cut and/or a signal for controlling the operating conditions of the refining process. This destination or recovery in value can consist of:
the recycle of the 350° C.+ or 525° C.+ cut as feedstock of the hydroconversion process,
the use of the 350° C.+ or 525° C.+ cut as fuel,
the use of the 350° C.+ or 525° C.+ cut as base for the formulation of an asphalt.

In particular, the monitoring method makes it possible to determine if the effluent can be further converted and recycled. Advantageously, the monitoring method thus makes it possible to optimize the recycle ratio of the process by adjusting the operating conditions by an appropriate control signal. If the effluent cannot be converted and recycled, it may then be used as fuel or asphalt base.

In particular, when the 525° C.+ cut is intended to be used as base for the formulation of an asphalt, it is possible to provide for measuring the softening point and the penetrability at 25° C. of the 525° C.+ cut. Advantageously, the 525° C.+ cut can exhibit a penetrability at 25° C. (measured according to the EN 1426 method) of less than or equal to 50-10⁻¹ mm and/or an RBT softening point (standard EN1427) of greater than or equal to 50° C., for example from 80 to 110° C.

The refining processes which can be monitored by the method according to the invention are described below.

Hydroconversion Processes

The feedstock consists of hydrocarbon feedstocks having an H/C ratio of at least 0.25. Thus, the hydrocarbon feedstocks which can be treated by these processes can be chosen from: atmospheric residues and vacuum residues, residues resulting from a deasphalting unit, deasphalted oils, visbroken (thermal cracking) effluents, 350° C.+ heavy effluents resulting from an FCC unit, including the FCC slurry (350° C.+) cut, shale oils, biomass, coal, petroleum coke from a delayed coker, or mixtures of one or more of these products. Other starting materials can also be cotreated with the petroleum residues: residues or wastes from tires, from polymers or resulting from road asphalts.

These processes are characterized by severe operating conditions: temperatures of 400° C. to 500° C., partial hydrogen pressure of 90 to 250 bar and large amount of catalyst (100 to 1000 tonnes to treat 100 t/h of feedstock).

These processes can in particular be carried out with a fixed bed catalysts or boiling or ebullating bed catalyst which are described below.

The fixed Bed Processes

The fixed bed processes typically consist of a series of adiabatic reactors comprising several catalytic beds. In each reactor, the gas and the liquid flow cocurrentwise from the top downward as a three-phase mixture, with the gas phase as continuous phase. Mention may in particular be made of the Hyvahl© process.

The ARDS/VRDS processes are processes for the desulfurization of atmospheric or vacuum residues. They make it possible to recover in value atmospheric or vacuum residues and to remove undesirable contaminants and thus to pretreat the feedstock for units located downstream in the refining scheme, such as FCC. The ARDS or VRDS processes normally operate at temperature conditions between 350 and 450° C. (limits included) and preferably between 380 and 410° C. (limits included). The total pressure is generally from 90 to 200 bar, preferably from 150 to 170 bar.

The effluents at the outlet of the ARDS/VRDS unit, for example the 370° C.+cuts, can comprise up to 5% by weight of asphaltenes.

The Boiling or Ebullating Bed Processes

The ebullating bed processes employ a supported catalyst which is suspended in the feedstock to be converted. The reactor is a column devoid of internal features where the gas flows from the bottom upward, which makes it possible to keep the catalyst in suspension. A fraction of the catalyst in the reactor is discharged and replaced with fresh catalyst (continuously or noncontinuously). An ebullating bed process makes possible an operation having unvarying operating conditions with an unvarying quality and performances with the passage of time. Mention may be made of the H-Oil© and LC-Fining© commercial processes.

The Processes of Slurry Type

The process, the catalyst of which (or its precursor) is in the form of a powder in suspension in the feedstock to be converted, subsequently known as “slurry-phase process” or slurry technology process, used for the hydroconversion of heavy hydrocarbon fractions, is a process known to a person skilled in the art. The technologies for the hydroconversion of residues in a slurry phase use a catalyst dispersed in the form of very small particles, the size of which is less than 500 μm, preferably from 1 to 200 nm, more particularly from 1 to 20 nm for fat-soluble precursors. The catalysts or their precursors are injected with the feedstock to be converted at the inlet of the reactors. The catalysts pass through the reactors with the feedstocks and the products in the course of conversion and then they are entrained with the reaction products outside the reactors. They are reencountered after separation in the heavy residual fraction, which can comprise from 0.05% to 5% (by weight) of catalyst fines. The catalysts used in the slurry are generally sulfur-comprising catalysts preferably comprising at least one element chosen from the group formed by Mo, Fe, Ni, W, Co, V, Cr and/or Ru; these elements can be coupled in order to form bimetallic catalysts. In this type of process, the catalysts used are generally unsupported catalysts, that is to say that the active phase is not deposited on the surface of a porous solid support but is well dispersed directly in the feedstock. The catalyst is generally provided in a nonactive form; reference is made to precursor. The sulfurization of the catalytic metal present in the precursor makes it possible to obtain the metal sulfides forming the active phase of the catalysts. The precursors are generally conventional chemicals (metal salt, phosphomolybdic acid, sulfur-comprising compounds, organometallic compounds or natural ores), which are converted into active catalysts in situ in the reactor or else in ex situ pretreatment units forming an integral part of the slurry-phase hydroconversion processes. The precursors are, for example, octoates, naphthenates, metallocenes, oxides or crushed ores.

The catalyst can be used in just one pass or in recycle mode.

When the catalyst is in a nonactive form, that is to say in the form of a precursor, it can be in the fat-soluble, water-soluble or solid (inorganic) form and is widely described in the literature.

The slurry-phase processes can operate according to different configurations. In one-pass mode, the catalyst at the reactor outlet is not recycled in the feedstock to be converted. The recycle mode is used when the catalyst retains an activity on conclusion of a first pass through the reactor. In recycle mode, the catalyst is concentrated after the reaction section and reinjected into the feedstock to be converted.

The amounts of catalysts which can be added to the feedstock, whether in “one-pass” mode or in “recycle” mode, are specified in table 1 below, by way of example.

TABLE 1

| | Mo | Fe | |
|---|---|---|---|
| Fat- | 50 to 6000 ppm (by weight) | 1000 ppm to 1% | (by weight) |
| soluble | | | |
| Water- | 300 to 6000 ppm (by weight) | 1500 ppm to 2% | (by weight) |
| soluble | | | |
| Solid | 300 to 6000 ppm (by weight) | 0.5% to 2% | (by weight) |
| (in- | | | |
| organic) | | | |

The slurry-phase hydroconversion process operates under very severe conditions in order to be able to convert complex feedstocks.

The process normally operates at temperature conditions of between 400 and 500° C. (limits included) and preferably between 410 and 470° C. (limits included). The hydrogen pressure is generally from 90 to 250 bar, preferably from 100 to 170 bar. The hourly liquid space velocity, expressed in h⁻¹, corresponds to the ratio of the flow rate of the feedstock to the reaction volume, is, for example, between 0.05 and 1.5 h⁻¹ (limits included).

This process can be carried out in one or more reactors, in series or in parallel, which can be of different types, for example an isothermal bubble column reactor.

Such a slurry-phase hydroconversion process can comprise, after a hydroconversion stage in at least one reactor comprising a slurry catalyst comprising at least one metal, a stage of separation of the hydroconversion effluent. This separation stage can comprise 3 substages:
First substage: the effluent from the hydroconversion stage is separated into a C6− cut and a C6+ cut at high temperature, for example from 300° C. to 400° C., and high pressure, approximately 150 bar, for example in a flash drum or a distillation column. The C6+ effluents resulting from this first substage are known as TLP (Total Liquid Product). The asphaltene content of said effluents can be from 7% to 20% by weight.
Second substage: the C6+ cut separated in the preceding stage is separated into a 350° C.− cut and a 350° C.+ cut at atmospheric pressure and at high temperature, for example from 300° C. to 400° C., for example in a distillation column. This asphaltene content of the 350° C.+ cut can be from 2% to 20% by weight.
Third substage: the 350° C.+ cut separated in the preceding stage is separated into a 525° C.− cut and a 525° C.+ cut by distillation under vacuum and at high temperature, for example of greater than 300° C. The 525° C.+ cut corresponds to the “final slurry” residue. Said residue consists of very complex molecules. A normal elemental composition of a final slurry residue is, for example, as follows:
carbon: 84-87% (by weight)
hydrogen: 7-14% (by weight)
heteroelements: sulfur from 2% to 6% (by weight), nitrogen from 0.5% to 2% (by weight)
metals: nickel and vanadium: 40 to 2000 ppm (by weight)
asphaltenes: 15-50% by weight
and optionally other elements in the form of traces.

The majority of the molecules exhibit aromatic ring groups optionally connected by paraffin chains. They can comprise more than 60% of carbon in unsaturated chains. The H/C atomic ratio is thus low.

FCC (Fluid Catalytic Cracking) Processes

The feedstocks treated are distillates obtained in vacuum distillation, visbreaking distillates and also residues insofar as their content of metals is acceptable.

The process is normally carried out at temperature conditions of 480 to 540° C. and pressure conditions of 2 to 3 bar with a specific cracking catalyst.

The unit produces heavy gasolines (160° C.-220° C.), an LCO cut (220° C.-350° C.) and a slurry cut (350° C+). The slurry cut can comprise from 0.1 to 8% by weight of asphaltenes.

Visbreaking Process

This process applies to atmospheric residues and to vacuum residues which can comprise from 2 to 25% by weight of asphaltenes.

The temperatures at the oven outlet are from 400 to 490° C. according to the feedstock to be treated. The unit can also comprise a maturing chamber where the reaction is continued. The pressure is from 5 to 12 bar. The severity of the cracking has to be controlled if an unstable heavy fuel oil is not to be obtained.

The heaviest fractions resulting from the visbreaking process are the atmospheric and vacuum residue (350° C+/500° C.). It is a fuel oil of improved viscosity with respect to the feedstock. The visbroken residue (VBR) can comprise from 15% to 30% by weight of asphaltenes.

NMR Measurement

The monitoring method according to the invention uses proton NMR to characterize the effluent.

The technique used is a technique which is based on the relaxation times of the protons (¹H) and makes it possible to characterize the system by the differences in mobility of the molecules. The sample to be analyzed is introduced into a permanent magnetic field B₀ and its response is studied after a specific excitation (pulse B₁). Reference is made to low field NMR when the magnetic fields Bₒ employed vary from 10 mT to 1.4 T approximately, i.e. for the ¹H proton of the Larmor frequencies v₀ ranging from 425 KHz to 60 MHz.

When the nuclei, that is to say the ¹H protons, are excited by one or more pulses of magnetic field B₁, they return to their equilibrium state according to several relaxation mechanisms. These relaxation phenomena are directly related to the mobility of the molecules and contribute information on their environment. It is possible to characterize these phenomena mainly by two relaxation times:
the longitudinal relaxation or spin-lattice relaxation (T₁), which corresponds to the return to equilibrium of the longitudinal magnetization (that is to say, magnetization parallel to the magnetic field B₀), denoted Mz,
the transverse relaxation or spin-spin relaxation (T₂), which corresponds to the return to equilibrium of the transverse magnetization (that is to say, magnetization in the plane perpendicular to the magnetic field B₀), denoted Mx.

The monitoring method according to the invention uses solely the acquisition of a signal representative of the transverse relaxation time T₂.

The NMR measurement can advantageously be carried out by means of a probe exhibiting a dead time of less than or equal to 11 μs. “Dead time” is understood to mean the time starting from which it is possible to record the signal.

Several NMR sequences can be used to measure the relaxation time T₂ of petroleum products. These are chosen from the sequences known to a person skilled in the art and which make it possible to measure the relaxation times of all of the phases of the sample (rigid phases and mobile phases), and advantageously the sequences which make it possible to determine the relaxation times T₂<30 μs. By way of example, the NMR sequences below can be used:
FID (Free Induction Decay), which makes possible the measurement of the decrease in the signal of the rigid phases. It can only be effectively used over the time range 0-200 μs as above 200 μs it is too sensitive to the nonhomogeneity of the magnetic field B₀.
The FID-CPMG (Carr-Purcell-Meiboom-Gill) sequence, which makes it possible to characterize the T₂. This sequence is a novel sequence which combines the measurement of the FID for 75 μs, then a measurement of the longer T₂ value(s) without being affected by the nonhomogeneity of the magnetic field B₀.

Other sequences not described here and known to a person skilled in the art can also be used.

Starting from the NMR signal thus acquired, the dynamic parameter(s) of the spins (such as transverse relaxation times) are extracted from a mathematical function which models the signal. This mathematical function can include a certain number of components each corresponding to a dynamic range of the entities of said effluent. This number of components can be modified iteratively in order to obtain the best mathematical model for adjusting the NMR signal. To each component there corresponds a transverse relaxation time T₂ and an intensity which is related to the amount of spins having a similar transverse relaxation time T₂, in other words related to the amount of spins having the transverse relaxation time T₂ corresponding to the component.

The greater the molecular dynamics, in other words the greater the mobility, the greater the transverse relaxation time.

Thus, the mathematical function modeling the acquired transverse relaxation signal makes it possible to estimate (to extract), for each component of the mathematical function:
the transverse relaxation time;
the intensity.

The number of components of the mathematical function can thus be two or more.

In a specific embodiment, the intensities can be extracted by modeling the acquired NMR signal by a mathematical function exhibiting two components, i.e. four unknowns (two transverse relaxation times and their associated intensities).

This function can be a function comprising at least one Gaussian part and at least one exponential part, or also a polynomial function or any other mathematical function suitable for adjusting the acquired NMR signal.

The unknowns of the mathematical function can be determined by means of conventional algorithms, for example of Levenberg-Marquardt type.

The modeling can be improved by a series of iterations.

From the intensities thus estimated (extracted), it is then possible to determine a value of parameter characteristic of the effluent, the transverse relaxation time signal of which has been acquired.

Advantageously, the parameter characteristic of the effluent can be a ratio of intensities, in particular whatever the number of components of the mathematical function. This ratio can in particular be a fraction of an intensity over the sum of all the intensities.

By way of example, if the mathematical model is a two-component model, the ratio can be A/B, B/A, A/A+B or B/A+B. Preferably, the parameter is the ratio A/A+B or B/A+B. Such a ratio makes it possible to ignore the amount of material used.

There are subsequently generated a signal for controlling the refining process as a function of the characteristic parameter.

Stages b) to e) of the monitoring method according to the invention can be employed by a management system, such as a processor of microprocessor, microcontroller or other type, for example a CPU (Central Processing Unit). The data measured can be stored in storage means which can be a random access memory RAM (Random Access Memory), an EEPROM (Electrically-Erasable Programmable Read-Only Memory) or other.

The management system can form part of the management system controlling the process.

### FIGURE

FIG. 1 is a graphical representation of the A/A+B ratio as a function of the level of conversion of a vacuum residue (example 1).

FIG. 2 is a graphical representation of the A/A+B ratio as a function of the degree of conversion of a pitch feedstock (example 2).

### EXAMPLES

The examples below are targeted at illustrating the effects of the invention and its advantages, without limiting the scope thereof.

In the examples, a refining process is carried out at different degrees of conversion.

Preparation of the samples: approximately 1 ml of the effluent to be analyzed by NMR is withdrawn and poured into the bottom of an NMR tube.

The measurements were carried out using a 0.47 T Bruker Minispec MQ20 spectrometer operating at 20 MHz for the proton, equipped with a 10 mm probe and having a dead time of 7 μs. The mean duration of the 90° and 180° pulses is 2.6 μs and 5.3 μs respectively.

The transverse relaxation signal was measured by a sequence of FID type.

The signal obtained was modeled by a mathematical function (1) comprising a Gaussian part and an exponential part and which can be written:

$${M}_{x} ( t ) = A \times exp ( - \frac{{t}^{2}}{{T}_{21}^{2}} ) + B \times exp ( - \frac{t}{{T}_{22}} ) \qquad ( 1 )$$

where:

M(x) is the transverse magnetization measured

t represents the time

T₂₁ corresponds to the transverse relaxation time of the least mobile entities in the sample

T₂₂ corresponds to the transverse relaxation time of the most mobile entities in the sample

A represents the intensity corresponding to the spins having the transverse relaxation time T₂₁

B represents the intensity corresponding to the spins having the transverse relaxation time T₂₂.

The proportion of the (100×A)/(A+B) fraction, also known as Gaussian fraction, is measured for different degrees of conversion of a refining process.

The level of conversion (or conversion) can be defined as being the ratio:

$$\frac{\begin{matrix}\% by weight of the 525 ° C . + cut in the feedstock - \\ \% by weight of 525 ° + cut in the effluents\end{matrix}}{\% by weight of the 525 ° C . + cut in the feedstock}$$

### Example 1

The refining process considered in the present example is a slurry-phase hydroconversion process.

The tests were carried out on a feedstock which is a vacuum residue of Ural-type crude, the characteristics of which are described in table 2 below. The catalyst employed is a fat-soluble molybdenum octoate salt injected at a content of 1000 ppm with respect to the feedstock. The tests are carried out at temperatures between 410 and 450° C. with a residence time of between 1 and 5 h under 150 bar of hydrogen. The effluents recovered are fractionated (naphtha, gas oil, vacuum distillates and vacuum residue). The low field NMR analysis is carried out on the vacuum residue cut corresponding to the 525° C.+ cut. The asphaltene content of this effluent varies, according to the level of conversion, from 10 to 60% by weight.

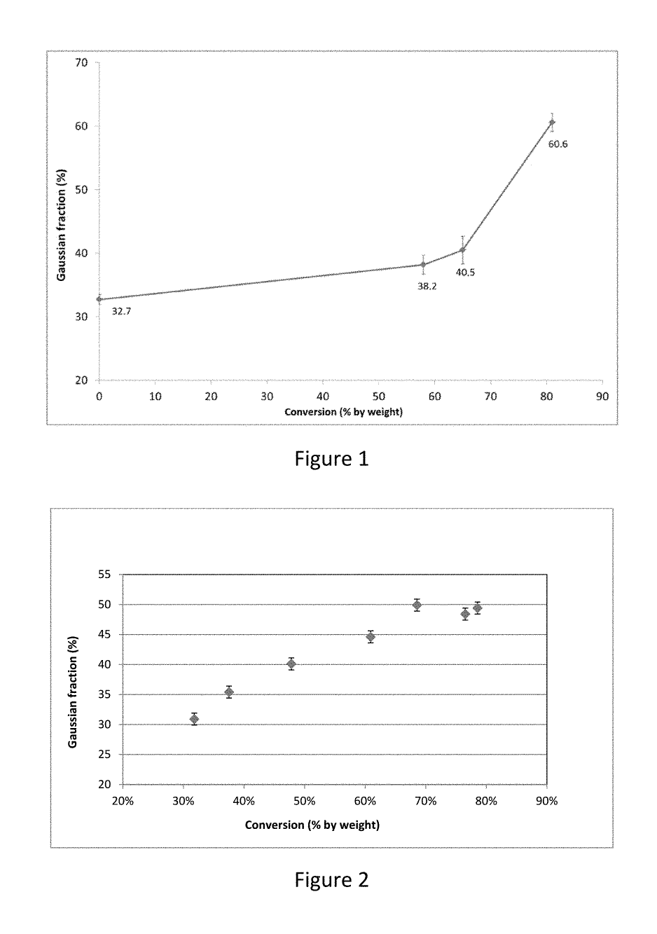

A graphical representation of the Gaussian fraction defined above is plotted as a function of the level of conversion, as represented in FIG. 1.

In this graph, it is seen that the Gaussian fraction suddenly increases from a certain level of conversion, which indicates a high risk of formation of coke. It is thus possible to direct the process by watching the Gaussian fraction of the effluent and to act on the parameters of the process in order to keep this Gaussian fraction in a value range where the risk of formation of coke is low.

### Example 2

The refining process considered in the present example is a slurry-phase hydroconversion process.

Catalytic tests in an autoclave reactor were carried out with a pitch feedstock, the characteristics of which are described in table 3 below. The catalyst employed is a fat-soluble molybdenum octoate salt injected at a content of 500 ppm (metal/feedstock ratio). The catalytic tests were carried out at temperatures between 410 and 440° C. and a residence time of between 20 minutes and 170 minutes under 150 bar of hydrogen.

The low field NMR analysis is carried out on the nonvolatile liquid fraction of the TLP (Total Liquid Product, 170° C.+ cut) effluents. The level of 525° C.+ conversion (or conversion) can be defined as being the ratio:

$$\frac{\begin{matrix}\% by weight of the 525 ° C . + cut in the feedstock - \\ \% by weight of 525 ° + cut in the effluents\end{matrix}}{\% by weight of the 525 ° C . + cut in the feedstock}$$

A graphical representation of the Gaussian fraction defined above is plotted as a function of the level of 525° C.+ conversion, as represented in FIG. 2. This level of conversion is adjusted by varying the reaction temperature and the reaction time.

In this graph, it is seen that the Gaussian fraction reaches a plateau from a level of conversion equal to approximately 70%. This means that the Gaussian fraction is substantially constant from this degree of conversion, which indicates the imminent formation of coke. It is thus possible to direct the process by watching the Gaussian fraction of the effluent and to act on the parameters of the process in order to keep this Gaussian fraction in a value range where the risk of formation of coke is low.

TABLE 2
characteristics of the feedstock of example 1

| | Ural VR |
|---|---|
| TBP cut 450-750° C. | |
| SP-160° C. (% by weight) | 0.0 |
| 160-350° C. (% by weight) | 0.0 |
| 350-525° C. (% by weight) | 2.6 |
| +525° C. (% by weight) | 97.2 |
| Density at 15° C. (kg/m³) | 1031.8 |
| CCR (% by weight) | 21 |
| Viscosity 100° C. in cSt | 4189.0 |
| Viscosity 135° C. in cSt | 458.5 |
| Elemental analysis | |
| Carbon (% by weight) | 85.50 |
| Hydrogen (% by weight) | 10.24 |
| Nitrogen (% by weight) | 0.74 |
| Oxygen (% by weight) | 0.52 |
| Sulfur (% by weight) | 3.14 |
| Ni (ppm) | 72 |
| Va (ppm) | 280 |
| Chlorine (ppm) | 15 |
| TAN in mg KOH/g | 0 |
| Basic nitrogen (ppm) | 2046 |
| S-value (standard ASTM D7157) | 4.42 |
| Sa | 0.77 |
| So | 1.02 |
| Xylene sediments (ppm) (standard ISO10307-2) | 316 |
| Asphaltenes (% by weight) | 7.00 |

TABLE 3
characteristics of the feedstock of example 2

| Description | C3-C4 pitch |
|---|---|
| TBP cut 470-750° C. | |
| SP-160° C. (% by weight) | 0 |
| 160-350° C. (% by weight) | 0 |
| 350-525° C. (% by weight) | 7.13 |
| +525° C. (% by weight) | 92.88 |
| Density at 15° C. (kg/m³) | 1093.2 |
| Elemental analysis | |
| S (% by weight) | 5.61 |
| H (% by weight) | 9.15 |
| Fe, ppm | 17 |
| Ni, ppm | 58.6 |
| V, ppm | 173 |
| CCR (% by weight) | 30.14 |
| Ntotal, ppm | 3582 |
| Nbasic, ppm | 1671 |
| S-value (standard ASTM D7157) | 5.06 |
| Sa value | 0.75 |
| So value | 1.29 |

1.-7. (canceled)

8. A method for monitoring a process for refining a feedstock of hydrocarbons, comprising:
a) acquiring a signal representative of the transverse relaxation time of the different entities of an effluent resulting from said refining process, in particular an effluent comprising solid entities, by proton NMR,
b) modeling the signal using a mathematical function comprising several components, each component corresponding to a transverse relaxation time T₂ and to an intensity which is related to the amount of spins having this transverse relaxation time T₂,
c) extracting from each of the components of the mathematical function:
the transverse relaxation time of each of the components,
the intensity of each of the components,
d) determining a value of parameter characteristic of the solid entities of said effluent from the intensity determined in stage c), said characteristic parameter being a ratio of intensities,
e) generating at least one signal for controlling the refining process as a function of said value of said characteristic parameter, the control signal being chosen from a signal for directing the operating conditions of the refining process and a signal for destination of the effluent, said stage of generation of a control signal comprising a stage of comparison of the value of the characteristic parameter of said effluent with at least one threshold value, determined according to one of the following ways:
i) operating said refining process at different levels of conversion or under different operating conditions for one and the same feedstock of hydrocarbons, and by carrying out stages a) to d) of the monitoring method, or
ii) carrying out stages a) to d) of the monitoring method on an effluent obtained during the operation of the refining process under known predetermined conditions.

9. The monitoring method as claimed in claim 8, in which the intensities are estimated by modeling the acquired signal by a mathematical function exhibiting two components.

10. The monitoring method as claimed in claim 8, in which the mathematical function is chosen from:
a function comprising at least one Gaussian part and at least one exponential part,
a polynomial function,
any other mathematical function suitable for adjusting the acquired NMR signal.

11. The monitoring method as claimed in claim 8, in which, during stage a), the signal representative of the transverse relaxation time is acquired by low field proton NMR.

12. The monitoring method as claimed in claim 8, in which the refining process is chosen from a vacuum or atmospheric distillation, a thermal conversion process, a fluid catalytic cracking process, a hydrocracking process, a hydrotreating process, a fixed bed hydroconversion process, a moving bed hydroconversion process, an ebullating bed hydroconversion process, a slurry-phase hydroconversion process or a process for the desulfurization of a vacuum distillation residue or of an atmospheric distillation residue.

13. The monitoring method as claimed in claim 8, in which the refining process is a slurry-phase hydroconversion process and in which process stage a) of acquisition of the NMR signal is carried out on the 350° C.+ or 525° C.+ cut of the effluent resulting from a slurry-phase hydroconversion process.

14. The monitoring method as claimed in claim 13, in which the control signal generated in stage e) comprises a signal for destination of the 350° C.+ or 525° C.+ cut, the destination of the 350° C.+ or 525° C.+ cut being chosen from the recycle as feedstock of the refining process, the use as fuel or the use as base for the formulation of an asphalt.
